(19) United States
(12) Patent Application Publication
(10) Pub. No.: US 2025/0321362 A1
(43) Pub. Date: Oct. 16, 2025

(54) COVER WINDOW, DISPLAY DEVICE COMPRISING THE COVER WINDOW, AND METHOD OF MANUFACTURING A COVER WINDOW

(71) Applicants: Samsung Display Co., LTD., Yongin-si (KR); Industry-University Cooperation Foundation KOREA AEROSPACE UNIVERSITY, Goyang-si (KR)

(72) Inventors: Chul Jin YIM, Yongin-si (KR); Yong Gyu CHOI, Goyang-si (KR); Jeong Seok LEE, Yongin-si (KR); Jin Hyuk LEE, Goyang-si (KR)

(21) Appl. No.: 18/980,066

(22) Filed: Dec. 13, 2024

(30) Foreign Application Priority Data
Apr. 16, 2024 (KR) 10-2024-0050484

(51) Int. Cl. G02B 1/14

(52) U.S. Cl. CPC G02B 1/14

(57) ABSTRACT

A cover window, a display device including the cover window, and a method of manufacturing a cover window are provided. The cover window includes a window substrate, and a protective layer disposed on the window substrate, wherein the protective layer includes an inorganic material including at least one of SiO₂ and ZrO₂ and a polymer resin including fluorine, a water contact angle of the protective layer is 105° or more, and surface hardness of the protective layer is 1 GPa or more.

This application claims priority to Korean Patent Application No. 10-2024-0050484 filed on Apr. 16, 2024, and all the benefits accruing therefrom under 35 U.S.C. § 119, the content of which in its entirety is herein incorporated by reference.

### BACKGROUND

### 1. Technical Field

The present disclosure relates to a cover window, a display device including the cover window, and a method of manufacturing a cover window.

### 2. Description of the Related Art

Electronic devices such as, for example, smartphones, tablet personal computers (PCs), digital cameras, laptop computers, navigation devices, and smart televisions that provide images to users include display devices for displaying the images.

The display device may include a display panel generating and displaying an image and a cover window covering the display panel. The cover window protects the display panel from foreign substances such as, for example, dust or water as well as external impacts and scratches.

### SUMMARY

Aspects of the present disclosure provide a cover window having flexibility and durability and which is capable of being applied to a foldable display device, a display device including the cover window, and a method of manufacturing a cover window.

Aspects of the present disclosure also provide a cover window with improved water repellency supportive of preventing a user's fingerprint or foreign substances such as, for example, dust from remaining, a display device including the cover window, and a method of manufacturing a cover window.

However, aspects of the present disclosure are not restricted to those set forth herein. The above and other aspects of the present disclosure will become more apparent to one of ordinary skill in the art to which the present disclosure pertains by referencing the detailed description of the present disclosure given herein.

According to an aspect of the present disclosure, a cover window includes a window substrate, and a protective layer disposed on the window substrate, wherein the protective layer includes an inorganic material including at least one of SiO₂ and ZrO₂ and a polymer resin including fluorine, a water contact angle of the protective layer is 105° or more, and surface hardness of the protective layer is 1 GPa or more.

In an embodiment, the polymer resin includes polytetrafluoroethylene (PTFE).

In an embodiment, a weight average molecular weight of the polymer resin is 20 g/mol to 1000 g/mol, and a glass transition temperature (Tg) of the polymer resin is 80° C. to 250° C.

In an embodiment, a thickness of the protective layer is 200 nm to 1500 nm.

In an embodiment, the inorganic material includes SiO₂, and the protective layer includes an inorganic layer including SiO₂ and a polymer layer including the polymer resin.

In an embodiment, the protective layer includes a first inorganic layer including SiO₂, a first polymer layer disposed on the first inorganic layer and including a polymer resin including the fluorine, a second inorganic layer disposed on the first polymer layer and including SiO₂, and a second polymer layer disposed on the second inorganic layer and including the polymer resin including the fluorine.

In an embodiment, a thickness of the first polymer layer and a thickness of the second polymer layer are different from each other.

In an embodiment, the thickness of the first polymer layer is smaller than the thickness of the second polymer layer.

In an embodiment, a thickness difference between the first inorganic layer and the first polymer layer is 2 nm to 100 nm.

In an embodiment, the inorganic material includes ZrO₂, and the protective layer is a single layer in which the inorganic material and the polymer resin are mixed with each other.

In an embodiment, an atomic ratio of fluorine in the protective layer is 0.5 to 50 times the atomic ratio of zirconium in the protective layer.

In an embodiment, the window substrate is formed of glass or plastic.

According to an aspect of the present disclosure, a display device includes a display panel, and a cover window disposed on the display panel, wherein the cover window includes a window substrate and a protective layer disposed on the window substrate, the protective layer includes an inorganic material including at least one of SiO₂ and ZrO₂ and a polymer resin including fluorine, a water contact angle of the protective layer is 105° or more, and surface hardness of the protective layer is 1 GPa or more.

According to an aspect of the present disclosure, a method of manufacturing a cover window, the method includes preparing a first target and a second target in a chamber of a sputtering device, the first target including an inorganic material including at least one of SiO₂ and ZrO₂ and the second target including a polymer resin including fluorine, and depositing a protective layer on a target substrate by sputtering the first target and the second target.

In an embodiment, the depositing of the protective layer on the target substrate by sputtering the first target and the second target includes sputtering the second target after sputtering the first target.

In an embodiment, a duration for which the first target is sputtered and a duration for which the second target is sputtered are equal to each other.

In an embodiment, power applied to the first target is equal to or greater than power applied to the second target.

In an embodiment, the method includes repeating the sputtering of the second target one or more times after sputtering the first target.

In an embodiment, the method includes increasing power supplied to the second target while repeating the sputtering of the second target.

In an embodiment, the depositing of the protective layer on the target substrate by sputtering the first target and the second target includes simultaneously sputtering the first target and the second target.

According to an aspect of the present disclosure, an electronic device, comprises a display device configured to provide an image, a processor configured to provide an image data signal to the display device, a memory configured to store a data information for operation, and a power module configured to generate power, wherein the display device comprises a display panel, and a cover window disposed on the display panel, wherein the cover window includes a window substrate and a protective layer disposed on the window substrate, the protective layer includes an inorganic material including at least one of SiO₂ and ZrO₂ and a polymer resin including fluorine, a water contact angle of the protective layer is 105° or more, and surface hardness of the protective layer is 1 GPa or more.

According to an embodiment, a cover window may have excellent surface hardness and surface water-repellent properties by including a protective layer including both an inorganic material such as, for example, silica (SiO₂) and/or zirconia (ZrO₂) and an organic material including fluorine.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of a display device according to an embodiment;

FIG. 2 is a cross-sectional view of a display member of FIG. 1;

FIG. 3 is a cross-sectional view of a display panel of FIG. 2;

FIG. 4 is a cross-sectional view of a cover window according to an embodiment;

FIGS. 5 to 9 are cross-sectional views of protective layers according to an embodiment, respectively;

FIG. 10 is a perspective view illustrating an unfolded state of the display device according to an embodiment;

FIG. 11 is a perspective view illustrating a folded state of the display device according to an embodiment;

FIG. 12 is a schematic cross-sectional view illustrating a sputtering device used in a manufacturing method of the display device according to an embodiment;

FIGS. 13A to 13C, 14A to 14D, and 15 to 17 illustrate confirmation results of physical properties of protective layers according to Example 1 of the present disclosure;

FIGS. 18, 19A to 19C, and 20 to 22 illustrate confirmation results of physical properties of protective layers according to Example 2 of the present disclosure;

FIGS. 23 and 24 illustrate confirmation results of physical properties according to Comparative Example 1;

FIGS. 25 and 26 illustrate confirmation results of physical properties according to Comparative Example 2;

FIGS. 27 and 28 illustrate confirmation results of physical properties according to Comparative Example 3;

FIG. 29 is a block diagram of an electronic device according to one embodiment of the present disclosure; and

FIG. 30 is a schematic diagram of an electronic device according to various embodiments of the present disclosure.

### DETAILED DESCRIPTION

Embodiments supported by the present disclosure will now be described more fully hereinafter with reference to the accompanying drawings, in which example embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will filly convey the scope of example aspects of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” and the like may be used herein to describe various elements, these elements should not be limited by these terms. These terms are used to distinguish one element from another element. For instance, a first element discussed below could be termed a second element without departing from the teachings supported by aspects of the present disclosure. Similarly, the second element could also be termed the first element.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within +30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

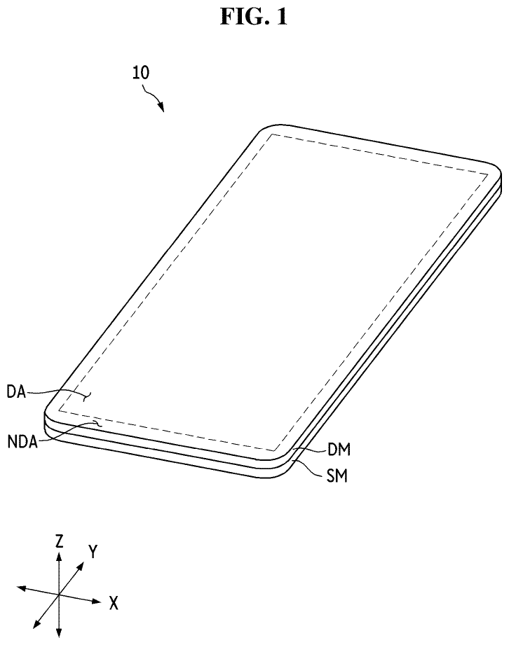

FIG. 1 is a perspective view of a display device according to an embodiment.

Hereinafter, a first direction X, a second direction Y, and a third direction Z are different directions, and cross each other. The first direction X, the second direction Y, and the third direction Z may perpendicularly cross each other. For example, the first direction X may be a transverse direction, the second direction Y may be a longitudinal direction, and the third direction Z may be a thickness direction. The first direction X, the second direction Y, and/or the third direction Z may include two or more directions. For example, in a cross-sectional view, the third direction Z may include an upward direction and a downward direction. In this case, one surface of a member disposed to face the upward direction may be referred to as an upper surface, and the other surface of the member disposed to face the downward direction may be referred to as a lower surface. However, these directions are illustrative and relative directions, and are not limited to those described herein.

A display device 10 is a device that displays a moving image or a still image, and may be used as a display screen of various products such as, for example, televisions, laptop computers, monitors, billboards, and the Internet of Things (IoT) as well as portable electronic devices such as, for example, mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

The display device 10 may have an approximately rectangular shape in a plan view. For example, the display device 10 may have short sides in the first direction X and long sides in the second direction Y in a plan view, as illustrated in FIG. 1. Corners of the display device 10 may be rounded. However, embodiments of the present disclosure are not limited thereto, and the display device 10 may have other polygonal shapes, a circular shape, or an elliptical shape in a plan view.

The display device 10 may be a rigid display device that is not folded or bent, but is not limited thereto. The display device 10 may include a foldable display device, a bendable display device, and a rollable display device.

The display device 10 may include a display area DA and a non-display area NDA.

The display area DA may display an image or video. The display area DA may have an approximately rectangular shape in a plan view, but is not limited thereto. The display area DA may include a plurality of pixels.

The display area DA is disposed on an upper surface of the display device 10, but is not limited thereto. The display area DA may be further disposed on at least one of a lower surface of the display device 10 and a side surface of the display device 10 between the upper surface and the lower surface.

The display area DA may be parallel to the first direction X and the second direction Y and may be approximately flat, but is not limited thereto. For example, at least a portion of the display area DA may be folded, bent, or curved such that the display area DA has a predetermined curvature.

The non-display area NDA may be disposed around the display area DA. The non-display areas NDA may surround the display area DA. In an embodiment, the display area DA may be formed in a rectangular shape, and the non-display area NDA may be disposed around four sides of the display area DA, but embodiments of the present disclosure are not limited thereto. A black matrix may be disposed in the non-display area NDA to prevent light emitted from adjacent pixels from being leaked.

The display device 10 may include a display member DM and a support member SM.

The display member DM provides an image. The display area DA may be disposed on the display member DM. The display member DM may be, for example, a display module.

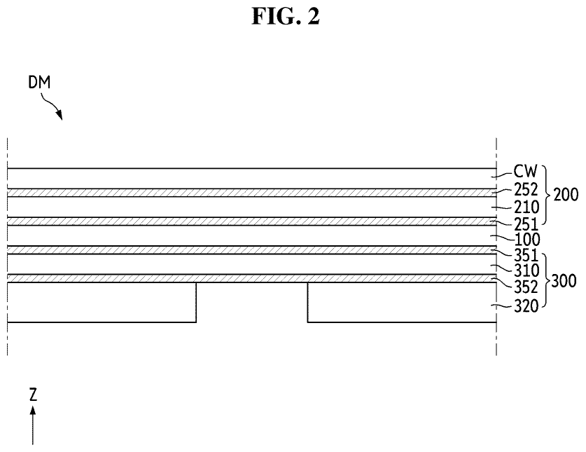

The display member DM forming the upper surface of the display device 10 and having a plate shape has been is illustrated in FIG. 1, but embodiments of the present disclosure are not limited thereto. The display member DM may have flexibility and be bent or folded into a shape corresponding to a type of the display device 1, such as, for example, a curved display device, a foldable display device, a bendable display device, and a rollable display device. In this case, although not illustrated, the display member DM may be further disposed on at least one of the side surface and the lower surface of the display device 10. A shape and an arrangement of a cover window CW (see FIG. 2) to be described later may also be variously changed into a flat or curved shape depending on the type of the display device 10 as described herein and/or an arrangement of the display member DM.

The support member SM supports the display member DM. The support member SM may include members for mounting the display member DM, such as, for example, a frame, a cover, and a housing. Although not illustrated, when the display device 10 is the foldable display device, the support member SM may further include a hinge connecting a plurality of frames (covers or housings) to each other.

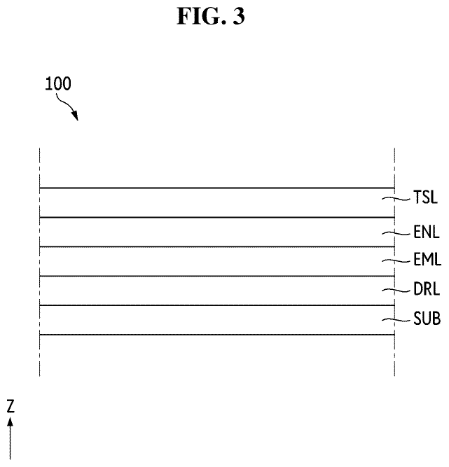

FIG. 2 is a cross-sectional view of a display member DM of FIG. 1. FIG. 3 is a cross-sectional view of a display panel 100 of FIG. 2.

Referring to FIGS. 1 and 2, the display member DM may include a display panel 100, an upper stacked structure 200 stacked on the display panel 100, and a lower stacked structure 300 stacked beneath the display panel 100.

The display panel 100 is a panel that displays a screen or an image, and examples of the display panel 100 may include not only a self-light emitting display panel such as, for example, an organic light emitting display panel (OLED), an inorganic light emitting display panel (inorganic EL), a quantum dot light emitting display panel (QED), a micro LED display panel (micro-LED), a nano LED display panel (nano-LED), a plasma display panel (PDP), a field emission display panel (FED), and a cathode ray display panel (CRT), but also a light receiving display panel such as, for example, a liquid crystal display panel (LCD) and an electrophoretic display panel (EPD).

The display panel 100 may further include a touch member. The touch member may be provided as a separate panel or film from the display panel 100 and attached onto the display panel 100 or may be provided in the form of a touch layer inside the display panel 100. In the following embodiments, a case where the touch member is provided inside the display panel 100 and included in the display panel 100 will be described by way of example, but embodiments of the present disclosure are not limited thereto.

Referring to FIG. 3, the display panel 100 may include a substrate SUB, a circuit driving layer DRL disposed on the substrate SUB, a light emitting layer EML disposed on the circuit driving layer DRL, an encapsulation layer ENL disposed on the light emitting layer EML, and a touch layer TSL disposed on the encapsulation layer ENL.

The substrate SUB may be a flexible substrate including a flexible polymer material such as, for example, polyimide. Accordingly, the display panel 100 may be curved, bent, folded, or rolled. In some embodiments, the substrate SUB may include a plurality of sub-substrates overlapping each other in the thickness direction with a barrier layer interposed between overlapping sub-substrates. In this case, each sub-substrate may be a flexible substrate.

The circuit driving layer DRL may be disposed on the substrate SUB. The circuit driving layer DRL may include a circuit driving the light emitting layer EML of the pixel. The circuit driving layer DRL may include a plurality of thin film transistors.

The light emitting layer EML may be disposed on the circuit driving layer DRL. The light emitting layer EML may include an organic light emitting layer. The light emitting layer EML may emit light with various luminances depending on a driving signal transferred from the circuit driving layer DRL.

The encapsulation layer ENL may be disposed on the light emitting layer EML. The encapsulation layer ENL may include an inorganic film or a stacked film of an inorganic film and an organic film.

The touch layer TSL may be disposed on the encapsulation layer ENL. The touch layer TSU is a layer sensing a touch input, and may function as the touch member. The touch layer TSL may include a plurality of sensing areas and sensing electrodes.

Referring to FIG. 2 again, the upper stacked structure 200 and the lower stacked structure 300 may be disposed on an upper surface and a lower surface of the display panel 100, respectively.

The upper stacked structure 200 may include a polarizing member 210 and a cover window CW that are sequentially stacked upward from the display panel 100.

The polarizing member 210 may be disposed on the upper surface of the display panel 100. The polarizing member 210 may polarize light passing therethrough. The polarizing member 210 may serve to reduce external light reflection.

The polarizing member 210 may be a polarizing film. The polarizing film may include a polarizing layer and protective substrates disposed on and beneath the polarizing layer. The polarizing layer may include a polyvinyl alcohol (PVA) film. The polarizing layer may be stretched in one direction. A stretching direction of the polarizing layer may be an absorption axis, and a direction perpendicular to the absorption axis may be a transmission axis. The protective substrates may be disposed on one surface and the other surface of the polarizing layer, respectively. The protective substrate may be formed of a cellulose resin such as, for example, triacetyl cellulose (TAC), a polyester resin, or the like, but is not limited thereto. Although not illustrated, the polarizing member may be replaced with a plurality of color filters and a black matrix disposed between the plurality of color filters.

The cover window CW may be disposed on an upper surface of the polarizing member 210. The cover window CW serves to protect the display panel 100.

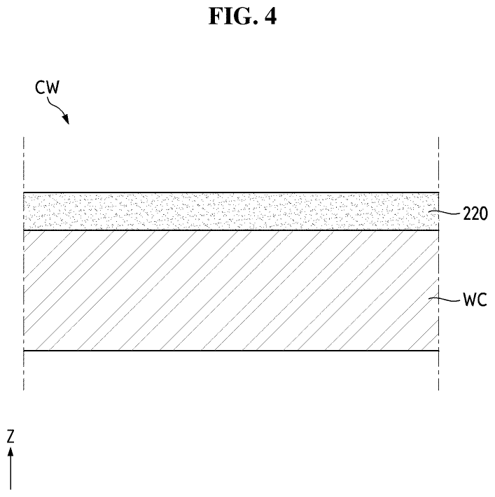

The cover window CW may be formed of a transparent material. The cover window CW has been illustrated as one layer in FIG. 2, but embodiments of the present disclosure are not limited thereto. The cover window CW may include a plurality of layers. A detailed stacked structure of the cover window CW will be described later with reference to FIG. 4.

The upper stacked structure 200 may include upper coupling members 251 and 252 coupling respective members stacked adjacent to each other to each other. The upper coupling members 251 and 252 may be optically transparent. For example, a first coupling member 251 may be disposed between the polarizing member 210 and the display panel 100 to couple the polarizing member 210 and the display panel 100 to each other, and a second coupling member 252 may be disposed between the cover window CW and the polarizing member 210 to couple the cover window CW and the polarizing member 210 to each other.

The lower stacked structure 300 may include a polymer film layer 310 and a heat dissipation member 320 that are sequentially stacked downward from the display panel 100.

The polymer film layer 310 may include a polymer film. The polymer film layer 310 may include, for example, polyimide (PI), polyethylene terephthalate (PET), polycarbonate (PC), polyethylene (PE), polypropylene (PP), polysulfone (PSF), polymethylmethacrylate (PMMA), triacetyl cellulose (TAC), a cycloolefin polymer (COP), and the like. The polymer film layer 310 may include a functional layer on at least one surface of the polymer film layer 310. The functional layer may include, for example, a light absorbing layer. The light absorbing layer may include a light absorbing material such as, for example, a black pigment or dye. The light absorbing layer is formed of black ink, and may be formed on the polymer film by a coating or printing method.

The heat dissipation member 320 may be disposed below the polymer film layer 310. The heat dissipation member 320 serves to diffuse heat generated from the display panel 100 or other components of the display device 1. The heat dissipation member 320 may include a heat dissipation sheet or a metal plate including graphite, carbon nanotubes, or the like.

The lower stacked structure 300 may include lower coupling members 351 and 353 coupling respective members stacked adjacent to each other to each other. For example, a third coupling member 351 may be disposed between the display panel 100 and the polymer film layer 310 to couple the display panel 100 and the polymer film layer 310 to each other, and a fourth coupling member 352 may be disposed between the polymer film layer 310 and the heat dissipation member 320 to couple the polymer film layer 310 and the heat dissipation member 320 to each other.

Although not illustrated, the lower stacked structure 300 may further include a buffering member. The buffering member may be disposed between the polymer film layer 310 and the heat dissipation member 320, for example.

Each of a plurality of layers constituting the display panel 100, the upper stacked structure 200, and the lower stacked structure 300 has been illustrated as one layer extending in left and right directions of FIG. 2 in FIG. 2, but embodiments of the present disclosure are not limited thereto. Although not illustrated, when the display device 10 is the foldable display device, at least one layer of the plurality of layers constituting the display panel 100, the upper stacked structure 200, and the lower stacked structure 300 may be disposed to be separated based on a specific area. In this case, bending stress of the display device 10 may be alleviated. For example, a plurality of heat dissipation members 320 may be disposed such that the two or more of the heat dissipation members 320 are separated from each other on a lower surface of the polymer film layer based on a specific area. In an example in which the display device 10 is a foldable display device, the specific area may be a folding area bent when the display device 10 is folded or bent.

FIG. 4 is a cross-sectional view of a cover window according to an embodiment.

Referring to FIGS. 1 to 4, the cover window CW may include a window substrate WC and a protective layer 220 disposed on the window substrate WC.

Hereinafter, for convenience of explanation, a surface positioned in a direction in which the image is displayed will be referred to as one surface, and a surface opposite to the one surface will be referred to as the other surface. The other surface may be a surface facing the display panel 100. As illustrated in FIG. 4, one surface and the other surface may be an upper surface and a lower surface, respectively, but are not limited thereto. In some aspects, hereinafter, ‘hardness’ may refer to surface hardness, but is not limited thereto.

Both the window substrate WC and the protective layer 220 may be formed of a transparent material.

The window substrate WC may be formed of glass or plastic.

Example implementations in which the window substrate WC is formed of plastic may support advantageous flexible characteristics such as, for example, folding or bending. Examples of the plastic that may be applied to the cover window CW may include, but are not limited to, polyimide, polyacrylate, polymethylmethacrylate (PMMA), polycarbonate (PC), polyethylenenaphthalate (PEN), polyvinylidene chloride, polyvinylidene difluoride (PVDF), polystyrene, an ethylene vinylalcohol copolymer, polyethersulfone (PES), polyetherimide (PEI), polyphenylene sulfide (PPS), polyallylate, triacetyl cellulose (TAC), cellulose acetate propionate (CAP), and the like. The cover window CW may include one or more of the plastic materials described herein. In an embodiment, the cover window CW may be formed of polyimide (PI) that is relatively freely folded, but is not limited thereto.

When the window substrate WC includes the glass, the glass may be ultra thin glass (UTG) or thin glass. In an example in which the glass is ultra thin glass or the thin glass, the glass may have flexible characteristics supportive of curving, bending, folding, or rolling of the glass. The glass of the window substrate WC may include soda lime glass, alkali aluminosilicate glass, borosilicate glass, or lithium aluminosilicate glass. The glass of the window substrate WC may include chemically strengthened or thermally strengthened glass in order to have high strength. Chemical strengthening may be achieved through an ion exchange treatment process in an alkali salt. The ion exchange treatment process may be performed twice or more.

In an embodiment, a thickness of the window substrate WC may be in the range of 0 μm to 1000 μm, for example. As another example, a thickness of the window substrate WC may be 100 μm to 800 μm. The window substrate WC may have a thickness significantly greater than a thickness of the protective layer 220.

The protective layer 220 may be disposed on one surface of the window substrate WC. In an embodiment, the protective layer 220 may be in direct contact with the window substrate WC. One surface of the protective layer 220 may be exposed to the outside to form an appearance of the cover window CW, and the other surface of the protective layer 220 may face the window substrate WC. The protective layer 220 may be disposed on the upper surface of the display panel 100, and may have excellent light transmittance in a wavelength band (380 nm to 700 nm) of a visible light region.

The protective layer 220 may include both an organic material and an inorganic material to function to block water from the outside while reinforcing surface hardness of the cover window CW. The protective layer 220 may be formed through a dry sputtering process in spite of including both the organic material and the inorganic material, and may thus have excellent mass productivity.

A water contact angle of the protective layer 220 may be 105° (degrees) or more. In the present disclosure, the water contact angle may be measured according to ASTM D5946. On one surface of the protective layer 220, that is, a surface of the protective layer 220 toward the outside of the display device 1, a water contact angle of the protective layer 220 with respect to a water droplet o 5 μl may be measured in an area within 100 μm using a contact angle goniometer (DSA 100 available from A. Kruss Optronic GmbH). The higher the water repellency, the greater the water contact angle may be. The protective layer 220 may include the organic material to have water repellency. In an embodiment, the water contact angle of the protective layer 220 may be 105° or more, 107° or more, or 110° or more. In an embodiment, the water contact angle of the protective layer 220 may be 120° or less or 115° or less. In an example in which the water contact angle of the protective layer 220 is in the range of 105° or more and 120° or less, the protective layer 220 may prevent external water from permeating into the display device 10 or prevent a user's fingerprint from remaining on a surface of the display device 1.

Surface hardness of the protective layer 220 may be 1 GPa or more. In the present disclosure, the surface hardness may be measured according to ISO 14577. On one surface of the protective layer 220, that is, the surface of the protective layer 220 toward the outside of the display device 1, an average value of corresponding values after measuring surface hardness 5 times at positions corresponding to each corner and a center point of an area of 1 cm² by maintaining an indenter for 100 seconds under a constant load (1.5 mN) using a nano indentation hardness tester (Nano Test Vantage Platform available from Micro materials Ltd.) may be decided as the surface hardness. In an embodiment, the surface hardness of the protective layer 220 may be 1 GPa or more or 1.05 GPa or more. In an embodiment, the surface hardness of the protective layer 220 may be 3.0 GPa or less or 2.50 GPa or less. In an example in which the surface hardness of the protective layer 220 is in the range of 1 GPa or more and 3.0 GPa or less, the cover window CW may have durability such that the cover window CW does not break or crack even when the display device 10 is folded or is repeatedly subjected to external force to be deformed.

A thickness of the protective layer 220 may be 200 nm to 1500 nm, 250 nm to 1000 nm, or 300 nm to 600 nm. The protective layer 220 may provide functionality and durability to the cover window CW in spite of having a small thickness. In an example in which the protective layer 220 is formed as a single layer, a thickness of the single layer may be the thickness of the protective layer 220. In an example in which the protective layer 220 is formed as a plurality of layers, a total thickness of the plurality of layers may be the thickness of the protective layer 220.

The organic material of the protective layer 220 may be a polymer resin including fluorine. The polymer resin may include polytetrafluoroethylene (PTFE). In an embodiment, a weight average molecular weight (MW) of the polymer resin may be 50 g/mol to 1000 g/mol, 50 g/mol to 500 g/mol, or 80 g/mol or 200 g/mol. In an example in which the weight average molecular weight (MW) of the polymer resin is in the above range, the polymer resin may be mixed with an inorganic material or deposited on an inorganic layer while having hardness appropriate for folding or fingerprint prevention. In an embodiment, a glass transition temperature (Tg) of the polymer resin may be 80° C. to 250° C. or 90° C. to 200° C. In an embodiment, a melting point (Tm) of the polymer resin may be 250° C. to 500° C. or 300° C. to 400° C.

The inorganic material of the protective layer 220 may include at least one of silica (SiO₂) and zirconia (ZrO₂). The protective layer 220 may have a great water contact angle and high transmittance in the visible light region by including silica (SiO₂) and zirconia (ZrO₂). A hybrid form of the organic material and the inorganic material in the protective layer 220 may be changed depending on a type of the inorganic material.

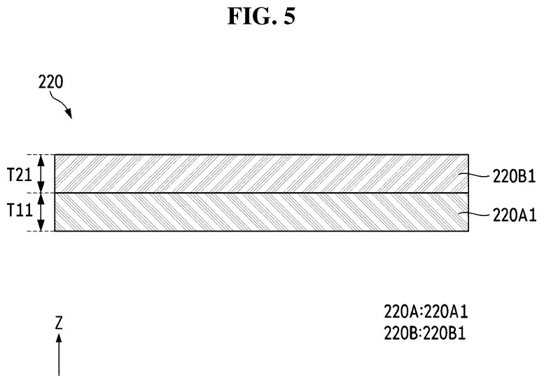

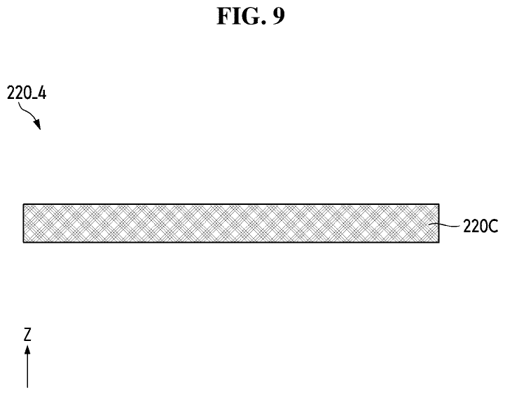

FIGS. 5 to 9 are cross-sectional views of protective layers 220 according to an embodiment, respectively. FIGS. 5 to 8 relate to cases where an inorganic layer 220A and a polymer layer 220B of the protective layer 220 are formed separately, and FIG. 9 relates to a case where a protective layer 220 is an organic-inorganic hybrid layer 220C in which an inorganic material and an organic material are formed in one layer.

In an embodiment, the protective layer 220 may include silica (SiO₂) as the inorganic material, and the protective layer 220 may include an inorganic layer 220A including the silica (SiO₂) and a polymer layer 220B including a polymer resin including fluorine. Referring to FIGS. 4 and 5, a first inorganic layer 220A1 including the silica (SiO₂) may be disposed on the window substrate WC, and a first polymer layer 220B including the polymer resin may be disposed on the first inorganic layer 220A1.

The protective layer 220 may have a multilayer structure including a plurality of inorganic layers 220A and a plurality of polymer layers 220B, and the inorganic layers 220A and the polymer layers 220B may be alternately disposed. The number of inorganic layers 220A and the number of polymer layers 220B may be the same as each other. In an example in which the protective layer 220 has the multilayer structure, the lowest layer, that is, a layer most adjacent to the window substrate WC, of the protective layer 220, may be the inorganic layer 220A including the silica (SiO₂), and the uppermost layer, that is, a layer furthest from the window substrate WC, of the protective layer 220, may be the polymer layer 220B including the polymer resin.

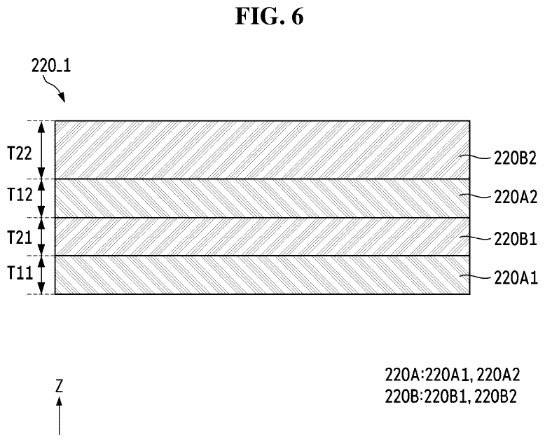

Referring to FIG. 6, an inorganic layer 220A of a protective layer 220_1 may include a first inorganic layer 220A1 and a second inorganic layer 220A2, and a polymer layer 220B of the protective layer 220_1 may include a first polymer layer 220B1 and a second polymer layer 220B2. The first inorganic layer 220A1, the first polymer layer 220B1, the second inorganic layer 220A2, and the second polymer layer 220B2 may be sequentially disposed on the window substrate WC.

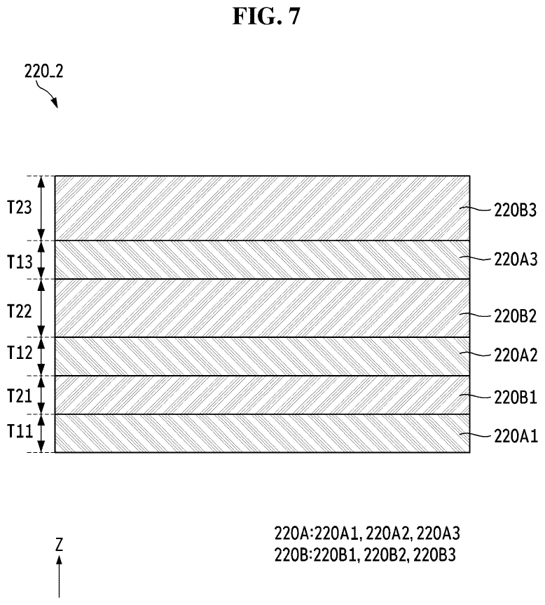

Referring to FIG. 7, an inorganic layer 220A of a protective layer 220_2 may include a first inorganic layer 220A1, a second inorganic layer 220A2, and a third inorganic layer 220A3, and a polymer layer 220B of the protective layer 220_2 may include a first polymer layer 220B1, a second polymer layer 220B2, and a third polymer layer 220B3. The first inorganic layer 220A1, the first polymer layer 220B1, the second inorganic layer 220A2, the second polymer layer 220B2, the third inorganic layer 220A3, and the third polymer layer 220B3 may be disposed sequentially on the window substrate WC.

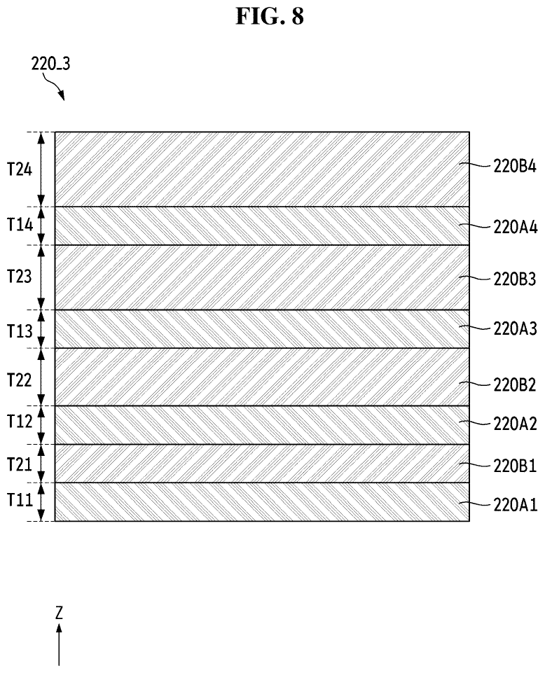

Referring to FIG. 8, an inorganic layer 220A of a protective layer 220_3 may include a first inorganic layer 220A1, a second inorganic layer 220A2, a third inorganic layer 220A3, and a fourth inorganic layer 220A4, and a polymer layer 220B of the protective layer 220_3 may include a first polymer layer 220B1, a second polymer layer 220B2, a third polymer layer 220B3, and a fourth polymer layer 220B4. The first inorganic layer 220A1, the first polymer layer 220B1, the second inorganic layer 220A2, the second polymer layer 220B2, the third inorganic layer 220A3, the third polymer layer 220B3, the fourth inorganic layer 220A4, and the fourth polymer layer 220B4 may be disposed sequentially on the window substrate WC.

Optical characteristics or surface characteristics of the protective layer 220 may be adjusted by adjusting thicknesses of the inorganic layer 220A and the polymer layer 220B. In an example in which power applied to a target in a sputtering process is adjusted, a thickness of the formed inorganic layer 220A or polymer layer 220B may be adjusted. The plurality of inorganic layers 220A may have different thicknesses T11, T12, T13, and T14, respectively, and the plurality of polymer layers 220B may have different thicknesses T21, T22, T23, and T24, respectively. Embodiments of the present disclosure support providing gradient functionality by increasing or decreasing the thickness of the inorganic layer 220A or the polymer layer 220B as a distance from the window substrate WC increases. The water contact angle of the protective layer 220 may increase or frictional force of a surface of the protective layer 220 may decrease. In an embodiment, the thickness T21 of the first polymer layer 220B1 may be smaller than the thickness T22 of the second polymer layer 220B2, the thickness T22 of the second polymer layer 220B2 may be smaller than the thickness T23 of the third polymer layer 220B3, and the thickness T23 of the third polymer layer 220B3 may be smaller than the thickness T24 of the fourth polymer layer 220B4.

The inorganic layer 220A and the polymer layer 220B adjacent to each other may have different thicknesses, and a thickness difference between the inorganic layer 220A and the polymer layer 220B adjacent to each other may be 2 nm to 100 nm. The inorganic layer 220A and the polymer layer 220B adjacent to each other may refer to the first inorganic layer 220A1 and the first polymer layer 220B1; the first polymer layer 220B1 and the second inorganic layer 220A2; the second inorganic layer 220A2 and the second polymer layer 220B2; the second polymer layer 220B2 and the third inorganic layer 220A3; the third inorganic layer 220A3 and the third polymer layer 220B3; the third polymer layer 220B3 and the fourth inorganic layer 220A4; or the fourth inorganic layer 220A4 and the fourth polymer layer 220B4.

In an embodiment, the protective layer 220 may include the zirconia (ZrO₂) as the inorganic material, and may be a single layer in which the zirconia (ZrO₂) and the polymer resin are mixed with each other. Referring to FIG. 9, a protective layer 220_4 may be an organic-inorganic hybrid layer 220C in which an inorganic material and an organic material are formed in one layer. Within the organic-inorganic hybrid layer (220C), zirconium of the zirconia (ZrO₂) and fluorine of the polymer resin may form a bond.

An atomic ratio of fluorine in the protective layer 220 may be 0.5 to 50 times or 1 to 20 times the atomic ratio of zirconium in the protective layer 220. In an example in which the atomic ratio of fluorine in the protective layer 220 is in the above range, the protective layer 220 having excellent water repellency may be obtained through a sputtering process. An elemental ratio may be obtained by energy dispersion x-ray spectrometer (EDS) component analysis.

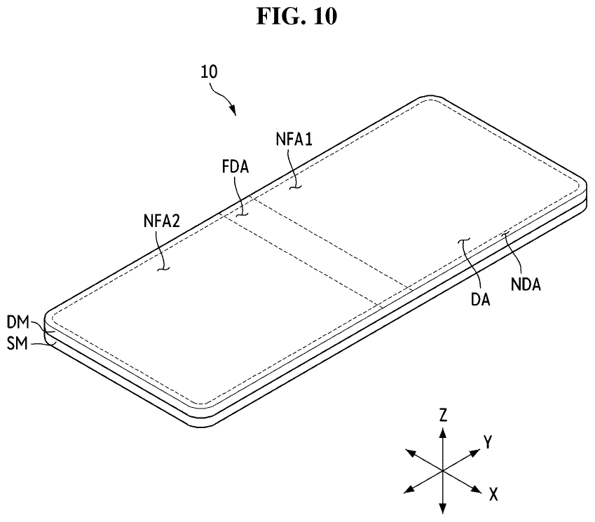

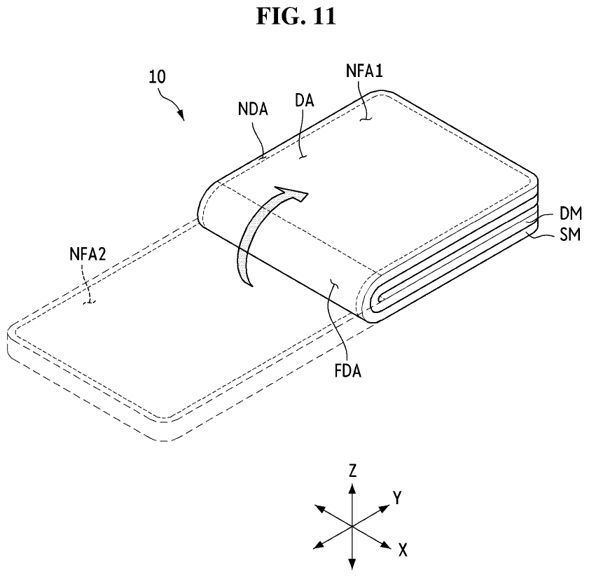

FIG. 10 is a perspective view illustrating an unfolded state of the display device according to an embodiment, and FIG. 11 is a perspective view illustrating a folded state of the display device according to an embodiment.

In an embodiment, the display device 10 may be a foldable device. The term “foldable device” as used herein is a device that may be folded, and is used as the meaning including not only a folded device, but also a device that may have both a folded state and an unfolded state. In some aspects, folding may include folding at an angle of about 180°, but is not limited thereto, and when a folding angle exceeds 180° or is less than 180°, for example, 90° or more and less than 180° or 120° or more and less than 180°, it may be understood that the display device is folded. In some aspects, when the display device is in a bent state out of an unfolded state even though the display device is not completely folded, the bent state may be referred to as the folded state. For example, even though the display device is bent at an angle of 90° or less, for cases in which a maximum folding angle is 90° or more, it may be expressed that the display device is in the folded state in order to be distinguished from the unfolded state. A radius of curvature of the display device when being folded may be 5 mm or less, may be preferably in the range of 1 mm to 2 mm or may be about 1.5 mm, but is not limited thereto.

In an embodiment, the display device 10 may be maintained in both the folded state and the unfolded state. The display device 10 may be folded in an in-folding manner in which the display area DA is disposed inside as illustrated in FIG. 11. In an example in which the display device 10 is folded in the in-folding manner, upper surfaces of the display device 10 may face each other. As another example, the display device 10 may be folded in an out-folding manner in which the display area DA is disposed outside. In an example in which the display device 10 is folded in the out-folding manner, lower surfaces of the display device 10 may face each other.

In an embodiment, the display device 10 may include a folding area FDA, a first non-folding area NFA1, and a second non-folding area NFA2. The folding area FDA may be an area where the display device 10 is folded, and the first non-folding area NFA1 and the second non-folding area NFA2 may be areas where the display device 10 is not folded.

The first non-folding area NFA1 may be disposed on one side, for example, the upper side, of the folding area FDA. The second non-folding area NFA2 may be disposed on the other side, for example, the lower side, of the folding area FDA. The folding area FDA may be an area curved with a predetermined curvature.

In an embodiment, the folding area FDA of the display device 10 may be specified at a specific position. The number of folding areas FDA specified at the specific position in the display device 10 may be one or two or more. In another embodiment, a position of the folding area FDA is not specified in the display device 1, and may be freely set in various areas.

In an embodiment, the display device 10 may be folded in the second direction Y. For this reason, a length of the display device 10 in the second direction Y may be reduced by approximately half, and thus, a user may conveniently carry the display device 10.

In an embodiment, a direction in which the display device 10 is folded is not limited to the second direction Y. For example, the display device 10 may be folded in the first direction X. In this case, a length of the display device 500 in the first direction X may be reduced by approximately half.

It has been illustrated in FIGS. 10 and 11 that each of the display area DA and the non-display area NDA overlaps the folding area FDA, the first non-folding area NFA1, and the second non-folding area NFA2, but embodiments of the present disclosure are not limited thereto. For example, each of the display area DA and the non-display area NDA may overlap at least one of the folding area FDA, the first non-folding area NFA1, and the second non-folding area NFA2.

The display member DM of the display device 10 of the foldable device may include the cover window CW described herein. The cover window CW is the same as that described herein, and a repeated description thereof is thus omitted.

Next, a cover window manufacturing method will be described.

It may be difficult to form a thin film including both an organic material and an inorganic material through a wet process, while in some cases, it may be possible to form a thin film including both an organic material and an inorganic material through a sputtering process.

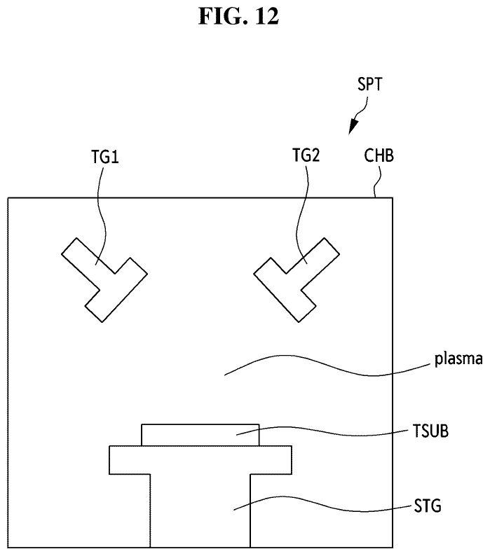

FIG. 12 is a schematic cross-sectional view illustrating a sputtering device SPT used in a manufacturing method of the display device 10 according to an embodiment.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

The method may include disposing a stage STG in a chamber CHB, and disposing a target substrate TSUB on the stage STG. The method may include preparing a first target TG1 and a second target TG2 in the same vacuum chamber CHB. The first target TG1 may be a target including an inorganic material such as, for example, silica or zirconia. The second target TG2 may be a target including an organic material, and may include the polymer resin including fluorine described herein. The first target TG1 and the second target TG2 may face the target substrate TSUB. The target substrate TSUB may be the window substrate WC described herein.

The method may include depositing protective layer 220 on the target substrate TSUB by sputtering the first target TG1 and the second target TG2. In this case, the method may include depositing the protective layer 220 by alternately sputtering the respective targets TG1 and TG2 or by simultaneously sputtering both the targets TG1 and TG2.

The method may include applying power of 25 W to 200 W to the respective targets TG1 and TG2, and the method may include depositing the protective layer 220 at room temperature. The method may include injecting argon (Ar) as a plasma generation gas and performing a radio frequency (RF) sputtering process.

In an example, the first target TG1 includes the silica (SiO₂), and the method may include forming the inorganic layer 220A on the target substrate TSUB by first applying power to the first target TG1 to generate plasma. Thereafter, the method may include forming the polymer layer 220B on the inorganic layer 220A by stopping the application of the power to the first target TG1 and applying power to the second target TG2. In some aspects, a duration (time) for which the first target TG1 is sputtered and a duration for which the second target TG2 is sputtered may be equal to each other. In some embodiments, the duration (time) for which the respective the targets TG1 and TG2 are sputtered may be 15 to 60 minutes, and a total deposition time for forming the protective layer 220 may be 2 to 3 hours.

In some embodiments, the method may include repeating the formation of the inorganic layer 220A and the formation of the polymer layer 220B, which may obtain the protective layer 220 in which the inorganic layers 220A and the polymer layers 220B are alternately disposed. In some aspects, the method may include adjusting the power applied to the first target TG1 or the second target TG2, which may accordingly adjust a thickness of the inorganic layer 220A or the polymer layer 220B. In an example in which the power applied to the second target TG2 is increased, the thickness of the polymer layer 220B may be increased. In some aspects, the power applied to the first target TG1 may be equal to or greater than the power applied to the second target TG2. For example, the method may include applying a power of 100 W to 200 W to the first target TG1 and applying a power of 50 W to 100 W to the second target TG2.

In an example, the first target TG1 includes the zirconia (ZrO₂), and the method may include forming the organic-inorganic hybrid layer 220C on the target substrate TSUB by simultaneously applying power to the first target TG1 and the second target TG2. A deposition duration (time) of the organic-inorganic hybrid layer 220C may be 1 hour to 2 hours. The power applied to the first target TG1 and the power applied to the second target TG2 may be the same as or different from each other, and may be 25 W to 200 W.

Hereinafter, examples will be described in detail in order to describe the present disclosure in detail. However, examples according to the present disclosure may be modified into various other forms, and it is not to be construed that the scope of the present disclosure is limited to examples to be described in detail below. Examples according to the present disclosure are provided in order to more completely describe the present disclosure to one of ordinary skill in the art.

### [Evaluation of Physical Properties of Cover Window]

### (1) Water Contact Angle

On one surface of the protective layer 220, that is, a surface of the protective layer 220 toward the outside of the display device 1, a water contact angle of the protective layer 220 with respect to a water droplet o 5 μl was measured in an area within 100 μm using a contact angle goniometer (DSA 100 available from A. Kruss Optronic GmbH).

### (2) Surface Hardness (Mean Hardness)

On one surface of the protective layer 220, that is, the surface of the protective layer 220 toward the outside of the display device 1, an average value of corresponding values after measuring surface hardness 5 times at positions corresponding to each corner and a center point of an area of 1 cm² by maintaining an indenter for 100 seconds under a constant load (1.5 mN) using a nano indentation hardness tester (Nano Test Vantage Platform available from Micro materials Ltd.) was decided as the surface hardness.

### (3) Surface Scanning Electron Microscope (SEM)

An image of an upper surface of the protective layer 220 or a thin film was captured with a scanning electron microscope (SEM). In this case, a magnification is 50,000.

### (4) Cross Section SEM

A specimen was cooled with liquid nitrogen and fractured, an image of a side surface of the specimen was captured with a scanning electron microscope (SEM), and a thickness was measured. In this case, a magnification is 50,000 or 10,000.

### (5) Light Transmittance

Light transmittance of the specimen was measured at a temperature of 85° C. and a relative humidity of 85%.

### (6) X-Ray Photoelectron Spectroscopy (XPS) Analysis

X-ray photoelectron spectroscopy (XPS) analysis was performed under conditions of X-ray: mono Al ka 1486.6 eV, 100 mm, Take off angle=45°, Reference: C 1s (at low B.E.)=285 eV using K-alpha available from Thermo Fuisher Scientific Inc.

(7) Energy Dispersion x-Ray Spectrometry (EDS) Analysis

Contents of inorganic material and organic material components, specifically, contents of elements, of the specimen may be analyzed through energy dispersion x-ray spectrometry (EDS) EDS analysis was performed using Osiris 200 kV TEM (FEI)—4 EDS detectors (available from Bruker Corporation).

### [Manufacture of Protective Layer]

A first target TG1 including an inorganic material and a second target TG2 including polytetrafluoroethylene (PTFE) were installed in a chamber of an RF sputtering device, and a glass substrate was set. In this case, a weight average molecular weight of polytetrafluoroethylene was 100.02 g/mol, a glass transition temperature (Tg) of polytetrafluoroethylene was 100° C. to 130° C., and a melting point of polytetrafluoroethylene was 327° C. An atmosphere was of the chamber was set to a low vacuum of 5×10⁻² Torr and set to a high vacuum of 5×10⁻⁵ Torr, 50 sccm of Ar was injected, and a process pressure was maintained at 10 mTorr.

In the case of alternate deposition in which an inorganic layer 220A and an polymer layer 220B are separately formed by alternately applying power to the first target TG1 and the second target TG2, the power was alternately applied to the respective targets TG1 and TG2 for N minutes and a protective layer 220 was formed for a total of 2 hours. N minutes were 15, 20, or 30 minutes.

In the case of simultaneous deposition in which an organic-inorganic hybrid layer 220C is formed by simultaneously applying power to the first target TG1 and the second target TG2, the protective layer 220 was formed by applying the power to the respective targets TG1 and TG2 for 1 to 2 hours.

### Example 1

Protective layers 220 were formed by alternately depositing inorganic layers formed of silica (SiO₂) and polymer layers formed of polytetrafluoroethylene (PTFE). The first target TG1 included silica (SiO₂), and the second target TG2 included polytetrafluoroethylene (PTFE).

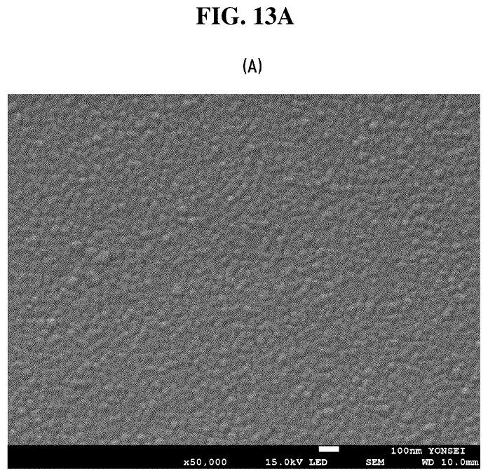

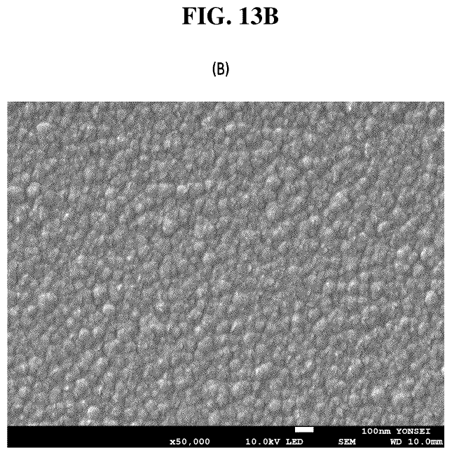

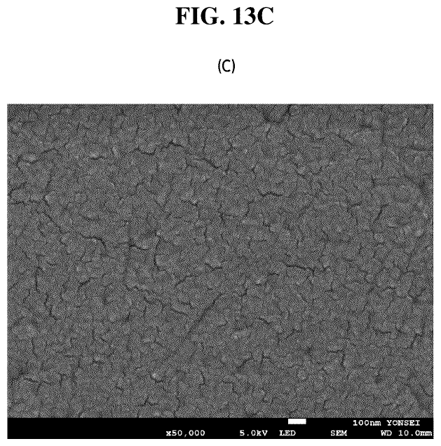

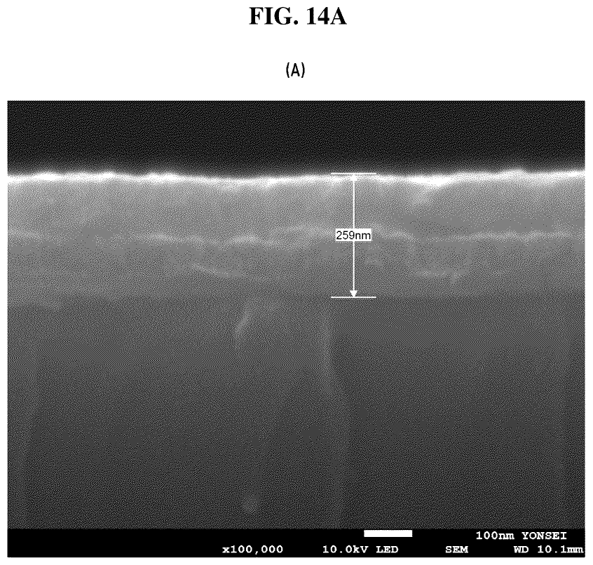

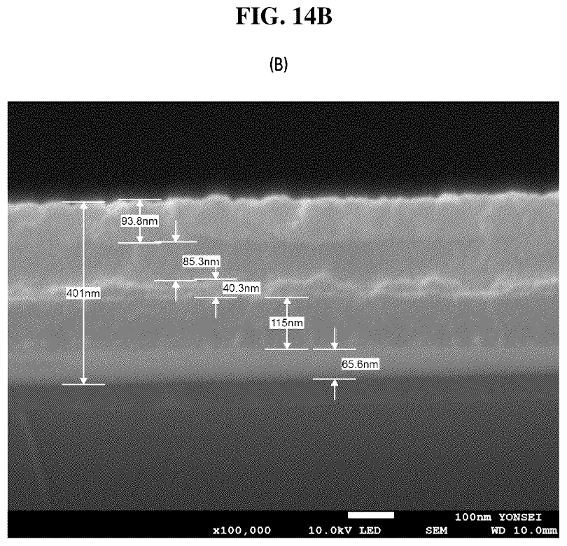

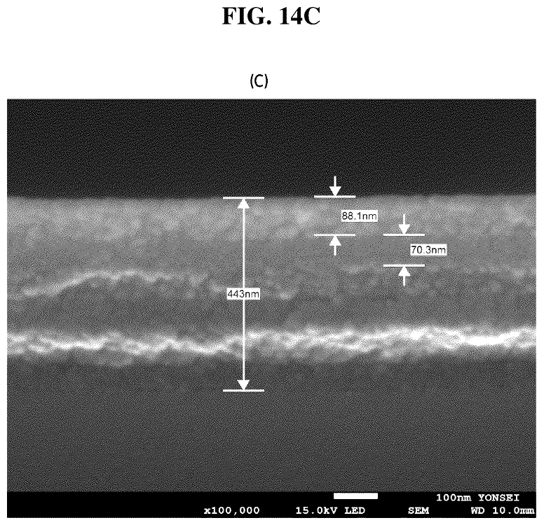

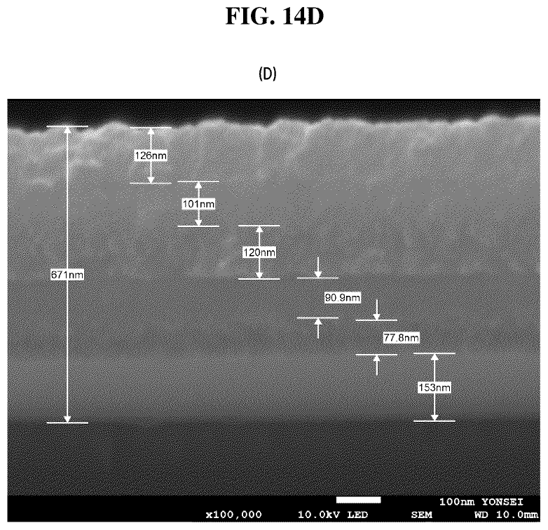

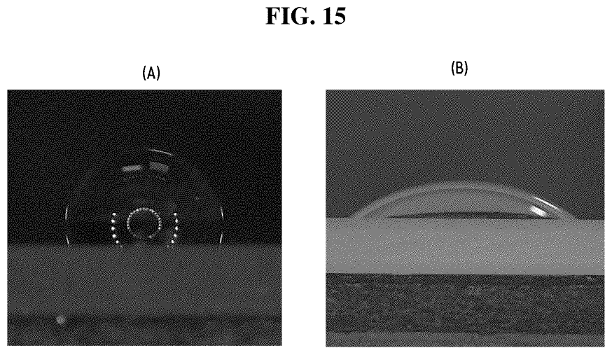

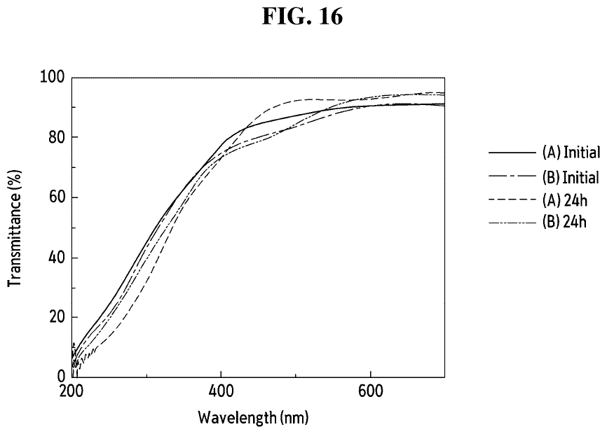

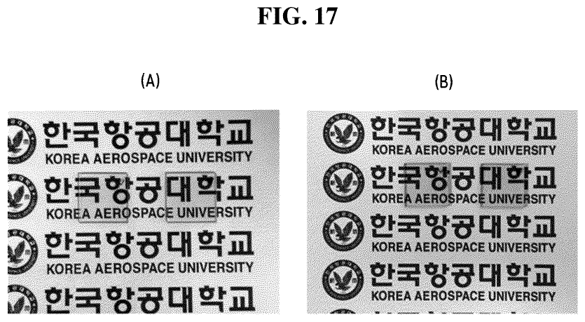

FIGS. 13A to 13C are images of upper surfaces of the protective layers 220 of Example 1 captured with an SEM (magnification: 50,000), and FIGS. 14A to 14D are images of cross sections of the protective layers 220 of Example 1 captured with an SEM (magnification: 10,000). FIG. 15 illustrates measurement results of water contact angles of Example 1, FIG. 16 illustrates measurement results of light transmittance of Example 1, and FIG. 17 illustrates confirmation results of visible light transmission of Example 1.

Surface hardness of the protective layers 220 of Example 1 was measured and illustrated in Table 1.

TABLE 1

| | First target: 200 W | First target: 200 W |
|---|---|---|
| Deposition condition | Second target: 75 W | Second target: 50 W |
| Mean hardness (GPa) | 1.08 | 1.27 |

The protective layers 220 of FIGS. 13A to 13C were formed by applying power of 200 W to the first target TG1 and power of 100 W to the second target TG2. A time for which power was applied to the respective targets TG1 and TG2 was 15 minutes in FIG. 13A, was 20 minutes in FIG. 13B, and was 30 minutes in FIG. 13C, and the protective layers 220 were deposited for a total of 2 hours. Referring to a surface SEM, it can be seen that the protective layers 220 are formed through sufficiently deposition.

The protective layer 220 of FIG. 14A was formed by alternately applying power of 150 W to the first target TG1 for 20 minutes and power of 50 W to the second target TG2 for 20 minutes. The protective layer 220 of FIG. 14B was formed by alternately applying power of 200 W to the first target TG1 for 20 minutes and power of 75 W to the second target TG2 for 20 minutes. The protective layer 220 of FIG. 14C was formed by alternately applying power of 200 W to the first target TG1 for 20 minutes and power of 100 W to the second target TG2 for 20 minutes. The protective layer 220 of FIG. 14D was formed by alternately applying power to the first target TG1 for 20 minutes and power to the second target TG2 for 20 minutes, and formed by alternately applying fixed power of 200 W to the first target TG1 for 20 minutes and power increased in the order of 50 W, 100 W, and 150 W to the second target TG2 for 20 minutes. Referring to FIGS. 14A to 14D, it may be confirmed that surfaces of the protective layers 220 are even and the inorganic layers 220A and the polymer layers 220B are alternately formed. In some aspects, it may be confirmed that as the power applied to the second target TG increases, a thickness of the polymer layer 220B increases.

(A) of FIG. 15 relates to a protective layer 220 formed by alternately applying power of 200 W to the first target TG1 for 20 minutes and power of 100 W to the second target TG2 for 20 minutes, and a water contact angle of 113° was measured. (B) of FIG. 15 relates to a thin film formed by alternately applying power of 200 W only to the first target TG1, and a water contact angle of 32° was measured. Referring to FIG. 15, it can be seen that the inclusion of the polymer layer 220B may improve water repellency of the protective layer 220.

FIGS. 16 and 17 relate to protective layers 220 formed by applying power of 200 W to the first target TG1 and power of 100 W to the second target TG2, wherein (A) is a case of alternately applying power of 200 W to the first target TG1 for 15 minutes and power of 100 W to the second target TG2 for 15 minutes and (B) is a case of alternately applying power of 200 W to the first target TG1 for 20 minutes and power of 100 W to the second target TG2 for 20 minutes. FIG. 16 illustrates initial transmittance of the protective layer 220 and transmittance of the protective layer 220 after 24 hours (24 h) at a temperature of 85° C. and a relative humidity of 85%. Referring to FIG. 16, it can be seen that transmittance of the protective layers 220 is excellent and optical characteristics of the protective layers 220 are maintained despite heat and humidity, in a visible light region. Referring to FIG. 17, it can be seen that letters disposed below the protective layer 220 are clearly visible, and thus, the transmittance of the protective layer 220 is excellent in the visible light region.

The protective layer 220 of Table 1 relates to a case where the power was alternately applied for 20 minutes under the above deposition conditions. It can be seen that hardness of Example 1 is far higher than hardness (0.32 GPa) of PTFE.

### Example 2

Protective layers 220 were formed by simultaneously depositing zirconia (ZrO₂) and polytetrafluoroethylene (PTFE). The first target TG1 included zirconia (ZrO₂), the second target TG2 included polytetrafluoroethylene (PTFE), and zirconia (ZrO₂) and polytetrafluoroethylene (PTFE) were deposited for 1 to 2 hours.

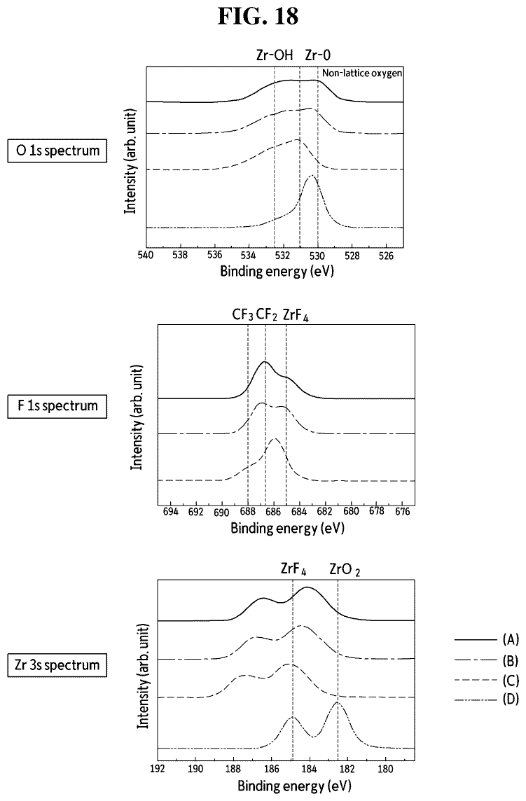

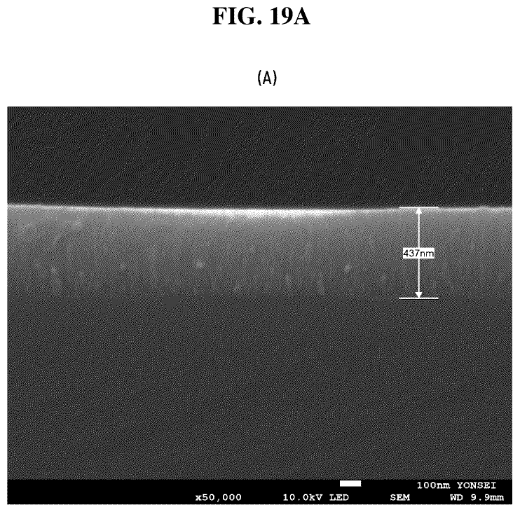

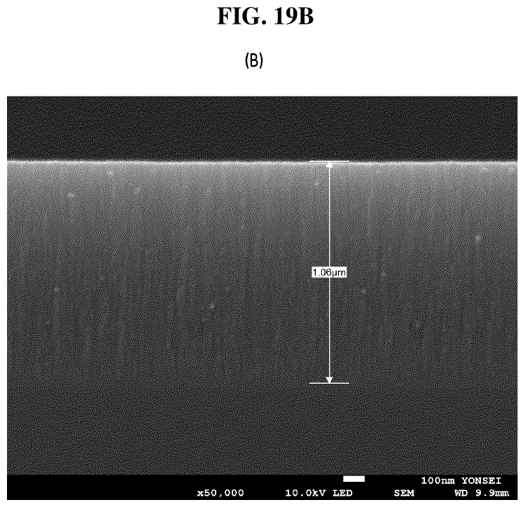

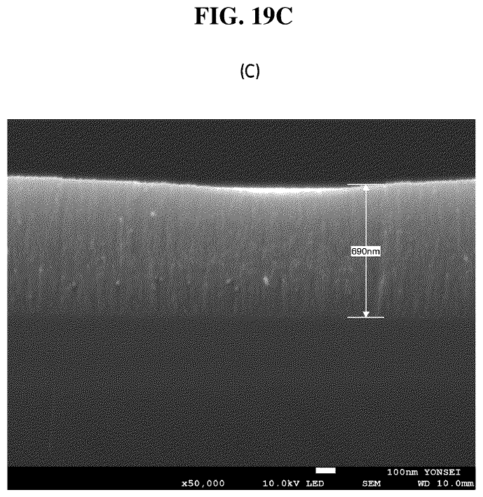

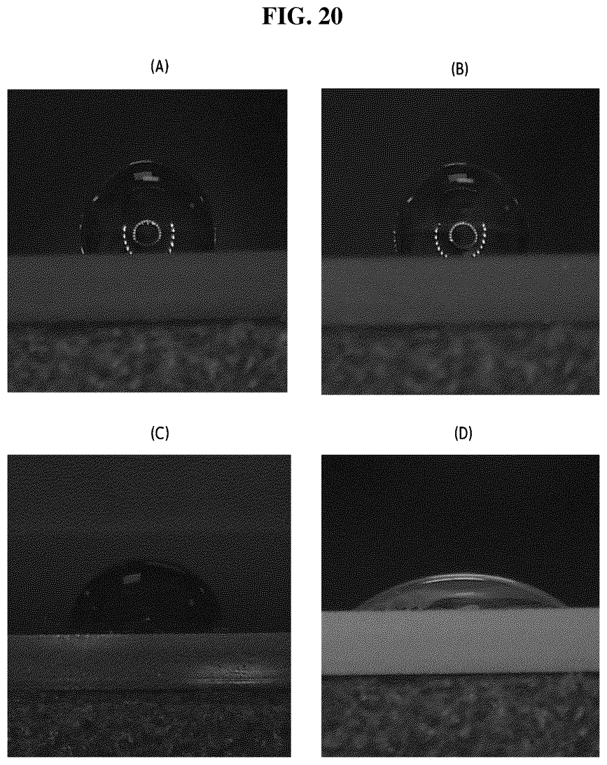

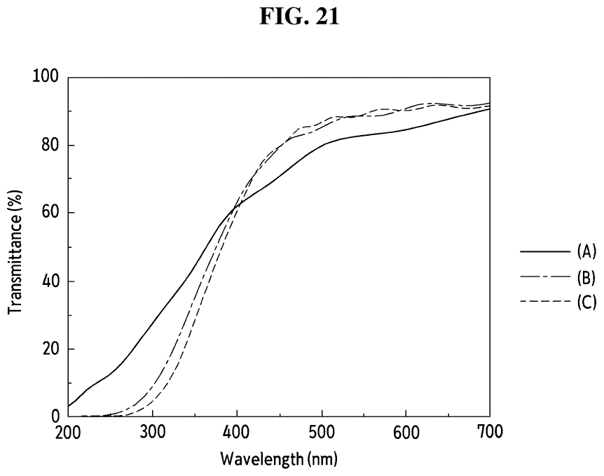

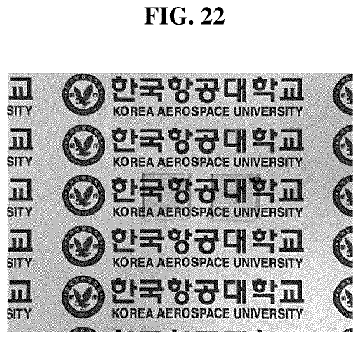

FIG. 18 relates to XPS structural analysis of Example 2, and FIGS. 19A to 19C are images of cross sections of the protective layers 220 of Example 2 captured with an SEM (magnification: 50,000). FIG. 20 illustrates measurement results of water contact angles of Example 2, FIG. 21 illustrates measurement results of light transmittance of Example 2, and FIG. 22 illustrates confirmation results of visible light transmission of Example 2.

Surface hardness of the protective layers 220 of Example 2 was measured and illustrated in Table 2.

TABLE 2

| | First target: 200 W | First target: 200 W |
|---|---|---|
| Deposition condition | Second target: 25 W | Second target: 50 W |
| Mean hardness (GPa) | 2.67 | 1.06 |

Content ratios of zirconium (Zr), oxygen (O), carbon (C), and fluorine (F) were measured by performing EDS analysis on the protective layers of Example 2, and relative ratios of atomic ratios of zirconium and fluorine were calculated and illustrated in Table 3.

TABLE 3

| | | | | | Relative |
|---|---|---|---|---|---|
| Deposition | Zr | O | C | F | ratio of |
| condition | (at %) | (at %) | (at %) | (at %) | [Zr]/[F] |
| First target: 100 W | 8.77 | 15.09 | 59.85 | 16.29 | 1:1.86 |
| Second target: 25 W | | | | | |
| First target: 100 W | 10.85 | 3.33 | 44.68 | 41.14 | 1:3.79 |
| Second target: 50 W | | | | | |
| First target: 200 W | 5.60 | 13.17 | 76.26 | 4.97 | 1:0.89 |
| Second target: 25 W | | | | | |
| First target: 200 W | 11.22 | 9.66 | 41.77 | 37.35 | 1:3.33 |
| Second target: 50 W | | | | | |

FIG. 18 relates a case where power of 200 W is applied to the first target TG1, wherein (A) relates a case where power of 200 W is applied to the second target TG2, (B) relates a case where power of 150 W is applied to the second target TG2, (C) relates a case where power of 100 W is applied to the second target TG2, and (D) relates a case where power is not applied to the second target TG2. Referring to FIG. 18, it may be confirmed that (A) to (C) in which the power is applied to the second target TG2 show different peaks from (D), and thus, zirconium and fluorine are bonded to each other.

The protective layer 220 of FIG. 19A was formed by applying power of 200 W to the first target TG1 and power of 100 W to the second target TG2. The protective layer 220 of FIG. 19B was formed by applying power of 200 W to the first target TG1 and power of 200 W to the second target TG2. The protective layer 220 of FIG. 19C was formed by applying power of 150 W to the first target TG1 and power of 150 W to the second target TG2. Referring to FIGS. 19A to 19C, it can be seen that surfaces of the protective layers 220 are even.

(A) of FIG. 20 relates to a protective layer 220 formed by applying power of 100 W to the first target TG1 and power of 200 W to the second target TG2, and a water contact angle of 110° was measured. (B) of FIG. 20 relates to a protective layer 220 formed by applying power of 150 W to the first target TG1 and the second target TG2, and a water contact angle of 107° was measured. (C) of FIG. 20 relates to a protective layer 220 formed by applying power of 200 W to the first target TG1 and the second target TG2, and a water contact angle of 110° was measured. (D) of FIG. 20 relates to a thin film formed by alternately applying power of 200 W only to the first target TG1, and a water contact angle of 37° was measured. Referring to FIG. 20, it can be seen that the protective layer 220 has improved water repellency by including PTFE.

FIG. 21 is a case where power of 100 W is applied to the first target TG1, wherein (A) is a case where power of 100 W is applied to the second target TG2, (B) is case where power of 150 W is applied to the second target TG2, and (C) is a case where power of 200 W is applied to the second target TG2. (A) of FIG. 22 relates to a protective layer 220 formed by applying power of 100 W to the first target TG1 and power of 150 W to the second target TG2. Referring to FIGS. 21 and 22, it can be seen that transmittance of the protective layers 220 is excellent in a visible light region. The terms “power applied to” and “power supplied to” may be used interchangeably herein.

Referring to Table 2, it can be seen that hardness of Example 2 is far higher than hardness (0.32 GPa) of PTFE.

Referring to Table 3, it can be seen that as the power applied to the second target TG2 increases, an atomic ratio of fluorine to zirconium increases, and it may be inferred that zirconium is bonded to oxygen and fluorine atoms.

### Comparative Example 1

A thin film was formed by simultaneously depositing titanium dioxide (TiO₂) and polytetrafluoroethylene (PTFE). The first target TG1 included titanium dioxide (TiO₂), the second target TG2 included polytetrafluoroethylene (PTFE), and titanium dioxide (TiO₂) and polytetrafluoroethylene (PTFE) were deposited for 1 hour.

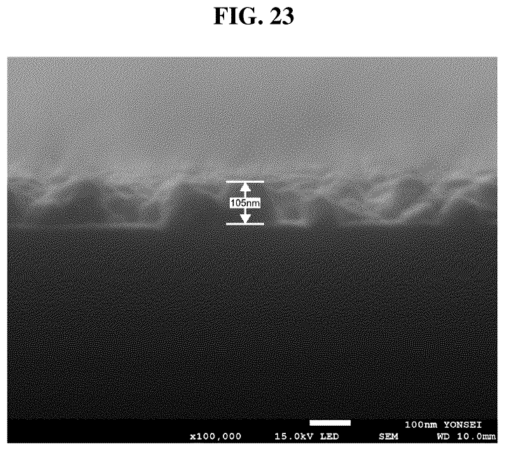

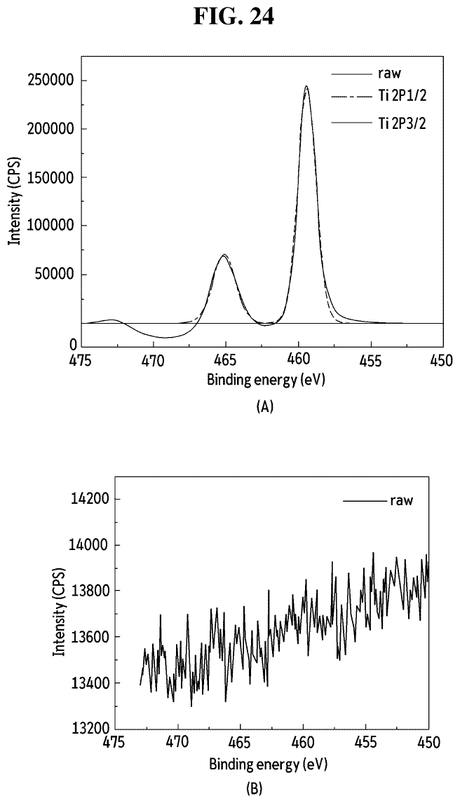

FIG. 23 is an image of a cross section of the thin film of Comparative Example 1 captured with an SEM, and FIG. 24 relates to XPS structural analysis of Comparative Example 1.

The thin film of FIG. 23 was formed by applying power of 100 W to the first target TG1 and the second target TG2. Referring to FIG. 23, it can be seen that a surface of the thin film is uneven and a thickness of the thin film is significantly small.

(A) of FIG. 24 is an XPS analysis result of a thin film of an inorganic material formed by applying power of 200 W only to the first target TG1, and (B) of FIG. 24 is an XPS analysis result of a thin film formed by applying power of 200 W to the first target TG1 and the second target TG2. Referring to FIG. 24, it can be seen that when titanium dioxide (TiO₂) and polytetrafluoroethylene (PTFE) are simultaneously deposited, titanium (Ti) is changed into TiF₄ having high sublimation properties through a plasma chemical reaction and does not participate in the formation of the thin film.

### Comparative Example 2

A thin film was formed by simultaneously depositing aluminum oxide (Al₂O₃) and polytetrafluoroethylene (PTFE). The first target TG1 included aluminum oxide (Al₂O₃), the second target TG2 included polytetrafluoroethylene (PTFE), and aluminum oxide (Al₂O₃) and polytetrafluoroethylene (PTFE) were deposited for 1 hour.

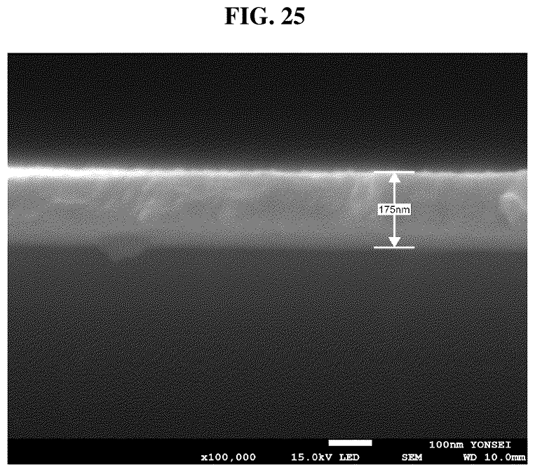

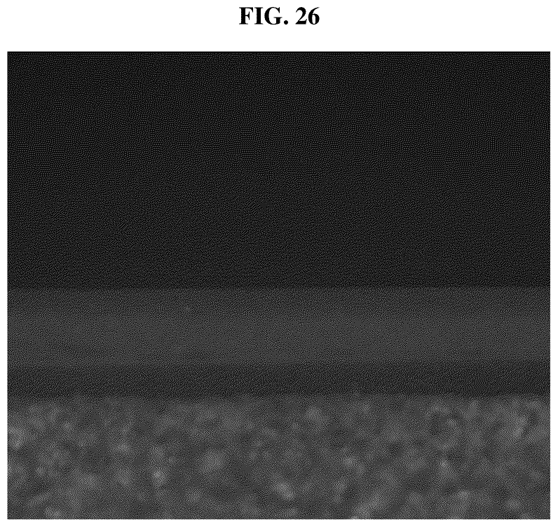

FIG. 25 is an image of a cross section of the thin film of Comparative Example 2 captured with an SEM, and FIG. 26 illustrates a measurement result of a water contact angle of Comparative Example 2.

The thin film of FIG. 25 and the thin film of FIG. 26 were formed by applying power of 200 W to the first target TG1 and the second target TG2. Referring to FIG. 25, it can be seen that the thin film is evenly formed, but a thickness of the thin film is significantly small.

Referring to FIG. 26, the thin film showed superhydrophilicity, such that a contact angle of the thin film might not be measured. The thin film included an organic material such as polytetrafluoroethylene, but the contact angle and water repellency of the thin film were not improved at all.

### Comparative Example 3

A thin film was formed by simultaneously depositing zinc oxide (ZnO) and polytetrafluoroethylene (PTFE). The first target TG1 included zinc oxide (ZnO), the second target TG2 included polytetrafluoroethylene (PTFE), and zinc oxide (ZnO) and polytetrafluoroethylene (PTFE) were deposited for 1 hour.

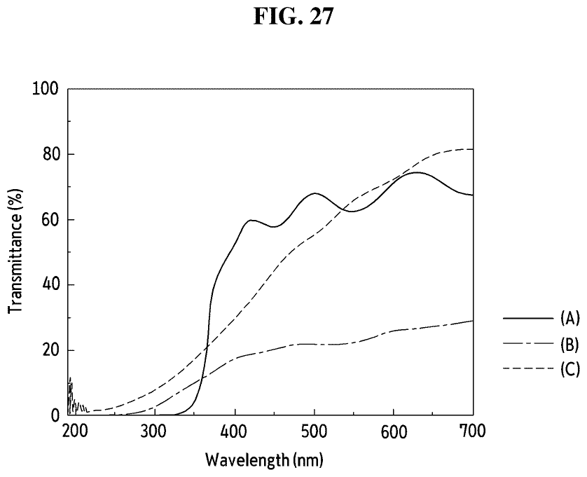

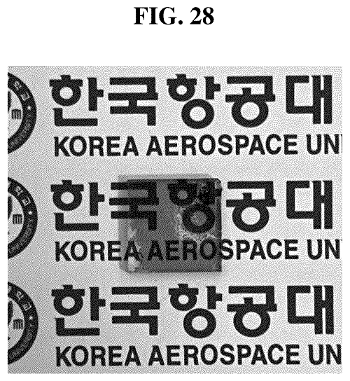

FIG. 27 illustrates measurement results of light transmittance of Comparative Example 3, and FIG. 28 illustrates a confirmation result of visible light transmission of Comparative Example 3.

FIG. 27 is a case where power of 200 W is applied to the first target TG1, wherein (A) is a case where power of 100 W is applied to the second target TG2, (B) is case where power of 150 W is applied to the second target TG2, and (C) is a case where power of 200 W is applied to the second target TG2. FIG. 28 relates to a thin film formed by applying power of 200 W to the first target TG1 and the second target TG2. Referring to FIGS. 27 and 28, it can be seen that transmittance of the protective layers 220 is low in a visible light region, such that the protective layers 220 are not appropriate for a cover window.

The embodiments of the present disclosure have been described hereinabove with reference to the accompanying drawings, but it will be understood by one of ordinary skill in the art to which the present disclosure pertains that various modifications and alterations may be made without departing from the technical spirit or technical features of the present disclosure. Therefore, it is to be understood that the embodiments described herein are illustrative rather than being restrictive in all aspects.

The display device according to one embodiment of the present disclosure can be applied to various electronic devices. The electronic device according to the one embodiment of the present disclosure includes the display device described above, and may further include modules or devices having additional functions in addition to the display device.

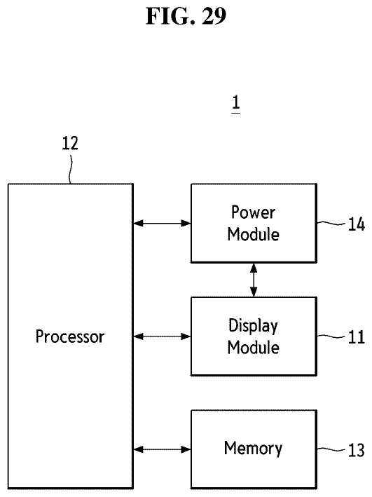

FIG. 29 is a block diagram of an electronic device according to one embodiment of the present disclosure.

Referring to FIG. 29, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

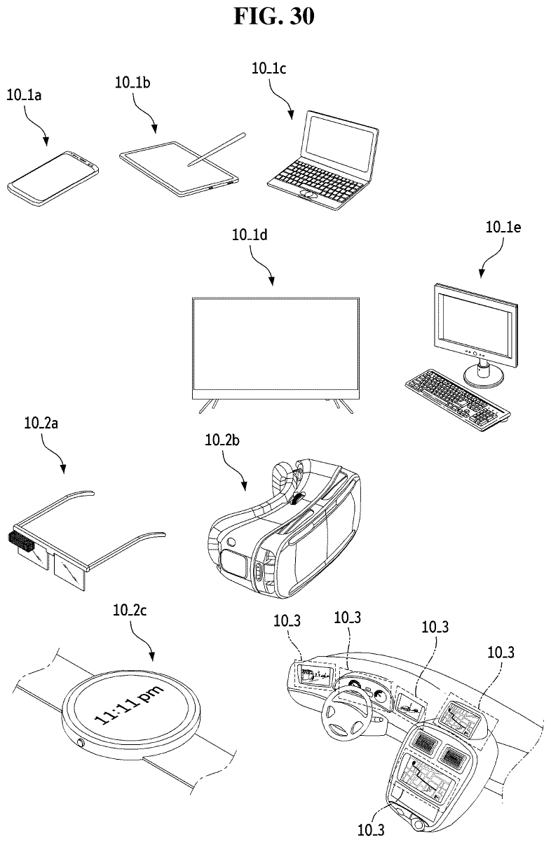

FIG. 30 is a schematic diagram of an electronic device according to various embodiments of the present disclosure.

Referring to FIG. 30, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In concluding the detailed description, those skilled in the art will appreciate that many variations and modifications can be made to the example embodiments without substantially departing from the principles of supported by aspects of the present disclosure. Therefore, the disclosed example embodiments of the present disclosure are used in a generic and descriptive sense and not for purposes of limitation.

What is claimed is:

1. A cover window comprising:
a window substrate; and
a protective layer disposed on the window substrate,
wherein:
the protective layer comprises:
an inorganic material comprising at least one of SiO₂ and ZrO₂; and
a polymer resin comprising fluorine,
a water contact angle of the protective layer is 105° or more, and
surface hardness of the protective layer is 1 GPa or more.

2. The cover window of claim 1, wherein the polymer resin comprises polytetrafluoroethylene (PTFE).

3. The cover window of claim 2, wherein:
a weight average molecular weight of the polymer resin is 20 g/mol to 1000 g/mol, and
a glass transition temperature (Tg) of the polymer resin is 80° C. to 250° C.

4. The cover window of claim 1, wherein a thickness of the protective layer is 200 nm to 1500 nm.

5. The cover window of claim 1, wherein:
the inorganic material comprises SiO₂, and
the protective layer comprises:
an inorganic layer comprising SiO₂; and
a polymer layer comprising the polymer resin.

6. The cover window of claim 5, wherein the protective layer comprises:
a first inorganic layer comprising SiO₂;
a first polymer layer disposed on the first inorganic layer and comprising a polymer resin comprising the fluorine;
a second inorganic layer disposed on the first polymer layer and comprising SiO₂; and
a second polymer layer disposed on the second inorganic layer and comprising the polymer resin comprising the fluorine.

7. The cover window of claim 6, wherein a thickness of the first polymer layer and a thickness of the second polymer layer are different from each other.

8. The cover window of claim 7, wherein the thickness of the first polymer layer is smaller than the thickness of the second polymer layer.

9. The cover window of claim 6, wherein a thickness difference between the first inorganic layer and the first polymer layer is 2 nm to 100 nm.

10. The cover window of claim 1, wherein:
the inorganic material comprises ZrO₂, and
the protective layer is a single layer in which the inorganic material and the polymer resin are mixed with each other.

11. The cover window of claim 10, wherein an atomic ratio of fluorine in the protective layer is 0.5 to 50 times an atomic ratio of zirconium in the protective layer.

12. The cover window of claim 1, wherein the window substrate is formed of glass or plastic.

13. A display device comprising:
a display panel; and
a cover window disposed on the display panel,
wherein:
the cover window comprises:
a window substrate; and
a protective layer disposed on the window substrate,
the protective layer comprises:
an inorganic material comprising at least one of SiO₂ and ZrO₂; and
a polymer resin comprising fluorine,
a water contact angle of the protective layer is 105° or more, and
surface hardness of the protective layer is 1 GPa or more.

14. A method of manufacturing a cover window, the method comprising:
preparing a first target and a second target in a chamber of a sputtering device, the first target comprising an inorganic material comprising at least one of SiO₂ and ZrO₂ and the second target comprising a polymer resin comprising fluorine; and
depositing a protective layer on a target substrate by sputtering the first target and the second target.

15. The method of claim 14, wherein the depositing of the protective layer on the target substrate by sputtering the first target and the second target comprises sputtering the second target after sputtering the first target.

16. The method of claim 15, wherein a duration for which the first target is sputtered and a duration for which the second target is sputtered are equal to each other.

17. The method of claim 15, wherein power applied to the first target is equal to or greater than power applied to the second target.

18. The method of claim 15, further comprising repeating the sputtering of the second target one or more times after sputtering the first target.

19. The method of claim 18, further comprising increasing power supplied to the second target while repeating the sputtering of the second target.

20. The method of claim 14, wherein the depositing of the protective layer on the target substrate by sputtering the first target and the second target comprises simultaneously sputtering the first target and the second target.

21. An electronic device, comprising:
a display device configured to provide an image;
a processor configured to provide an image data signal to the display device;
a memory configured to store a data information for operation; and
a power module configured to generate power,
wherein the display device comprises:
a display panel; and
a cover window disposed on the display panel,
wherein:
the cover window comprises:
a window substrate; and
a protective layer disposed on the window substrate,
the protective layer comprises:
an inorganic material comprising at least one of SiO₂ and ZrO₂; and
a polymer resin comprising fluorine,
a water contact angle of the protective layer is 105° or more, and
surface hardness of the protective layer is 1 GPa or more.
